(19) United States
(12) Patent Application Publication
(10) Pub. No.: US 2023/0197407 A1
(43) Pub. Date: Jun. 22, 2023

(54) UPPER ELECTRODE MECHANISM, CURRENT CONTROL METHOD FOR RADIO FREQUENCY COIL, AND SEMICONDUCTOR PROCESSING APPARATUS

(71) Applicant: BEIJING NAURA MICROELECTRONICS EQUIPMENT CO., LTD., Beijing (CN)

(72) Inventors: Jing WEI, Beijing (CN); Gang WEI, Beijing (CN); Jing YANG, Beijing (CN); Chen NIU, Beijing (CN); Xingfei MAO, Beijing (CN)

(21) Appl. No.: 17/926,413

(22) PCT Filed: May 12, 2021
(86) PCT No.: PCT/CN2021/093250

§ 371 Date: Nov. 18, 2022

(30) Foreign Application Priority Data
May 18, 2020 (CN) 202010419642.0

(51) Int. Cl. H01J 37/32

(52) U.S. Cl. CPC H01J 37/321; H01J 37/32568; H01J 37/32183; H01J 37/32577; H01J 2237/24564; H01J 2237/3343

(57) ABSTRACT

An upper electrode mechanism of a semiconductor process apparatus includes a radio frequency (RF) coil including two parallelly-connected branches, two current sensors each arranged on one of the branches and configured to detect a branch current of a corresponding one of the two branches, and a current adjustment device connected to the RF coil and configured to adjust the branch current of at least one branch of the two branches according to the detected branch currents to cause the branch currents of the two branches to be equal.

### TECHNICAL FIELD

The present disclosure generally belongs to the semiconductor apparatus technology field and, more particularly, to an upper electrode mechanism of a semiconductor processing apparatus, a current control method for a radio frequency coil, and a semiconductor processing apparatus.

### BACKGROUND

In a plasma etching apparatus, it is very important to improve etching uniformity across a wafer.

In a current inductively coupled plasma apparatus, a radio frequency (RF) source outputs RF power and is connected to an outer coil and an inner coil through a matcher. A connection bar member is used as a transitional connection between the matcher and the coil. Through a matching function of the matcher, an induced magnetic field is generated by the inner coil and the outer coil, which generates an inductively coupled plasma in a chamber through a dielectric window. In the RF source, radial uniformity of the plasma is controlled by adjusting a ratio of the current in the inner coil and the current in the outer coil.

However, when the current is adjusted in the above method to realize the radial uniformity of the plasma, a part of the connection bar part between the matcher and the coil connected to each coil can be considered to be a part of coil impedance. Due to differences in mechanical structures (e.g., a length of branches of the connection bar) and differences in distribution parameters caused by a space limitation of a ground part, distribution parameters of the connection bar parts connected in series on each parallelly-connected branch are different. Thus, the total inductance value of the branch is different, which causes the currents of two branches connected in parallel to be different. Thus, the energy of the plasma coupled to the chamber through the dielectric window is uneven, which causes the problem that the etching processing is uneven.

### SUMMARY

The purpose of embodiments of the present disclosure is to provide an upper electrode mechanism of a semiconductor processing apparatus and a semiconductor processing apparatus, to solve the problem in the existing technology that the energy of the plasma coupled to the chamber through the dielectric window is uneven due to different currents of the parallelly-connected branches of the coils, especially the problem of uneven etching process when the radial uniformity of the plasma is achieved by adjusting the ratio of the currents in the inner coil and the outer coil.

In order to solve the above technical problems, embodiments of the present disclosure are implemented as follows.

In a first aspect, embodiments of the present disclosure provide an upper electrode mechanism of a semiconductor processing apparatus, including a radio frequency (RF) coil, a current sensor, and a current adjustment device, wherein:

the RF coil includes at least two parallelly-connected branches;

a current sensor is arranged on each of the branches and is configured to detect a branch current corresponding to the branch; and

the current adjustment device is connected to the RF coil and is configured to adjust a branch current of at least one of the branches according to the detected branch current to cause branch currents of the branches to be equal.

In some embodiments, the current adjustment device includes a capacitance adjustment assembly. The capacitance adjustment assembly is connected to the at least two parallelly-connected branches to adjust capacitance of the at least one of the branches.

In some embodiments, the capacitance adjustment assembly includes at least two adjustable capacitors. The at least two adjustable capacitors are arranged on the at least two parallelly-connected branches in a one-to-one correspondence.

In some embodiments, the current adjustment device includes a first connection bar, a second connection bar, and a mobile connection bar. The first connection bar is connected to an RF source through a matcher. The second connection bar is connected to the at least two parallelly-connected branches. The mobile connection bar is movably connected to the first connection bar and the second connection bar. A connection point of the mobile connection bar and the first connection bar is movable along the first connection bar. A connection point of the mobile connection bar and the second connection bar is movable along the second connection bar.

In some embodiments, the first connection bar and the second connection bar are parallel to each other. The mobile connection bar is perpendicular to the first connection bar and the second connection bar. Two ends of the mobile connection bar are movably connected to the first connection bar and the second connection bar, respectively.

In some embodiments, the current adjustment device further includes two connection assemblies configured to movably connect the two ends of the mobile connection bar to the first connection bar and the second connection bar, respectively.

Each connection assembly includes a first washer, a second washer, an elastic member, and a screw. A strip-shaped groove is formed on each of the first connection bar and the second connection bar, threaded holes cooperating with the screws are formed at the two ends of the mobile connection bar, respectively. A through-hole for one of the screws to pass through is formed on each of the first washer and the second washer.

The first washer and the second washer are arranged oppositely. The first washer is movably connected to the first connection bar and the second connection bar.

The second connection bar is attached to a corresponding one of the connection assemblies. The elastic member is arranged between the first washer and the second washer. The screw passes from a side of the second washer away from the first washer through the through-hole of the second washer, the elastic member, the through-hole of the first washer, and the stripe-shaped groove of one of the first connection bar and the second connection bar corresponding to the connection assembly in sequence, and is threadedly connected to the threaded hole of the mobile connection bar.

In some embodiments, the RF coil includes an inner coil and an outer coil. Both the inner coil and the outer coil include at least two parallelly-connected branches.

In a second aspect, embodiments of the present disclosure provide a semiconductor processing apparatus, including a process chamber. The process chamber is provided with the upper electrode mechanism according to the first aspect.

In a third aspect, embodiments of the present disclosure provide a current control method of a radio frequency (RF) coil in a semiconductor processing apparatus, applied to the upper electrode mechanism according to the first aspect, including:

detecting branch currents of the at least two parallelly-connected branches of the RF coil; and

according to the detected branch currents, adjusting the branch current of the at least one of the branches to cause the branch currents of the branches to be equal.

In some embodiments, the process chamber is provided with the upper electrode mechanism according to the first aspect. Adjusting the branch current of the at least one of the branches to cause the branch currents of the branches to be equal according to the detected branch currents includes:

according to the detected branch currents, adjusting a capacitance value of an adjustable capacitor on the at least one of the branches to cause the branch currents of the branches to be equal.

In some embodiments, the process chamber is provided with the upper electrode mechanism according to the first aspect. Adjusting the branch current of the at least one of the branches to cause the branch currents of the branches to be equal according to the detected branch currents includes:

adjusting lengths of connection parts of the first connection bar and the second connection bar between the respective branches and the macher by moving the mobile connection bar to cause the branch currents of the branches to be equal.

In some embodiments, the process chamber is provided with the upper electrode mechanism according to the first aspect. Adjusting the lengths of the connection parts of the first connection bar and the second connection bar between the respective branches and the macher by moving the mobile connection bar includes:

loosening the screw to reduce a compression amount of the elastic member;

moving the two ends of the mobile connection bar along the stripe-shaped groove to adjust the positions of the connection points where the two ends of the mobile connection bar are connected to the first connection bar and the second connection bar, respectively; and

tightening the screw to increase the compression amount of the elastic member to fix the mobile connection bar at the adjusted positions.

It can be seen from the technical solutions provided by the above embodiments of the present disclosure that in embodiments of the present disclosure, by detecting the branch current of the corresponding branch of the at least two parallelly-connected branches of the RF coil through the current sensors, the branch current of the at least one branch may be adjusted by the current adjustment device according to the detected branch currents to cause the branch currents of the branches to be equal. Thus, the situation that the energy of the plasma coupled to the chamber through the dielectric window is uneven due to the different currents of the parallelly-connected branches of the coil may be avoided. Thus, the uniformity of the etching process may be ensured.

### BRIEF DESCRIPTION OF THE DRAWINGS

In order to describe the technical solution of embodiments of the present disclosure or in the existing technology more clearly, the following briefly introduces the accompanying drawings that are used in the description of embodiments or the existing technology. Obviously, the accompanying drawings described below are merely some embodiments of the present disclosure. For those of ordinary skill in the art, other drawings can also be obtained according to these drawings without any creative effort.

FIG. 1 is a schematic architectural diagram of a semiconductor processing apparatus.

FIG. 2A is a schematic top view of an outer coil of FIG. 1.

FIG. 2B is a schematic top view of an inner coil of FIG. 1.

FIG. 3 is a schematic architectural diagram of a semiconductor processing apparatus according to some embodiments of the present disclosure.

FIG. 4 is a schematic diagram of a radio frequency equivalent circuit according to some embodiments of the present disclosure.

FIG. 5A is a schematic structural diagram of a current adjustment device according to some embodiments of the present disclosure.

FIG. 5B is a schematic structural cross-section diagram of a current adjustment device according to some embodiments of the present disclosure.

FIG. 6 is a schematic diagram of another radio frequency equivalent circuit according to some embodiments of the present disclosure.

FIG. 7 is a schematic flowchart of a current adjustment method of a semiconductor processing apparatus according to some embodiments of the present disclosure.

FIG. 8 is a schematic flowchart of another current adjustment method of a semiconductor processing apparatus according to some embodiments of the present disclosure.

FIG. 9 is a schematic block diagram showing a principle of a current adjustment device of a semiconductor processing apparatus according to some embodiments of the present disclosure.

FIG. 10 is a schematic block diagram showing another principle of a current adjustment device of a semiconductor processing apparatus according to some embodiments of the present disclosure.

### DETAILED DESCRIPTION OF THE EMBODIMENTS

Embodiments of the present disclosure provide an upper electrode mechanism of a semiconductor processing apparatus and the semiconductor processing apparatus.

In order to help those skilled in the art better understand the technical solutions of the present disclosure, the technical solutions of embodiments of the present disclosure will be clearly and completely described below with reference to the accompanying drawings of embodiments of the present disclosure. Obviously, the described embodiments are only some embodiments of the present disclosure, but not all the embodiments. Based on embodiments of the present disclosure, all other embodiments obtained by those of ordinary skill in the art without creative efforts shall fall within the scope of the present disclosure.

### Embodiment 1

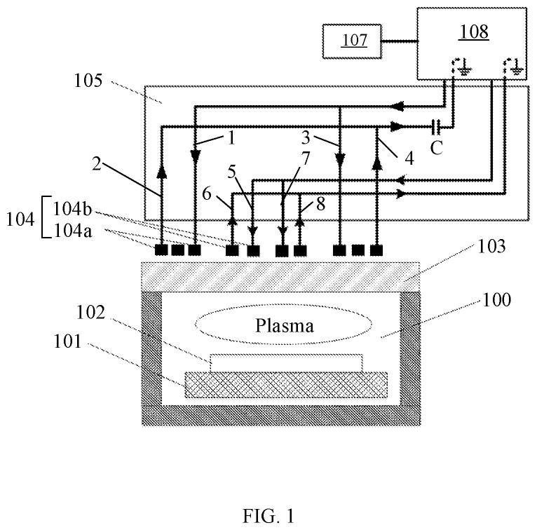

The embodiment provides an upper electrode mechanism of a semiconductor processing apparatus. The semiconductor processing apparatus may include an inductively coupled plasma emission spectrometer (ICP), a capacitively coupled plasma (CCP) apparatus, a microwave plasma apparatus, an electron cyclotron resonance (ECR) apparatus, etc. For example, a structure of the semiconductor processing apparatus is shown in FIG. 1. The semiconductor processing apparatus includes a process chamber 100, a radio frequency (RF) source 107, a matcher 108, and an upper electrode mechanism. The process chamber 100 is provided with a base 101 configured to carry a wafer 102. The base 101 may be, for example, an electrostatic chuck. In addition, a dielectric window 103 is arranged at a top of the process chamber 100. The dielectric window 103 may be usually made of materials such as quartz or ceramics. The upper electrode mechanism includes an RF coil 104 (including an outer coil 104a and an inner coil 104b) and a connection bar 105. The RF coil 104 is arranged above the dielectric window 103 and is electrically connected to the matcher 108 through the connection bar 105. The RF source 107 may apply RF power to the radio frequency coil 104 through the matcher 108 to excite the reaction gas in the process chamber 100 to form a plasma.

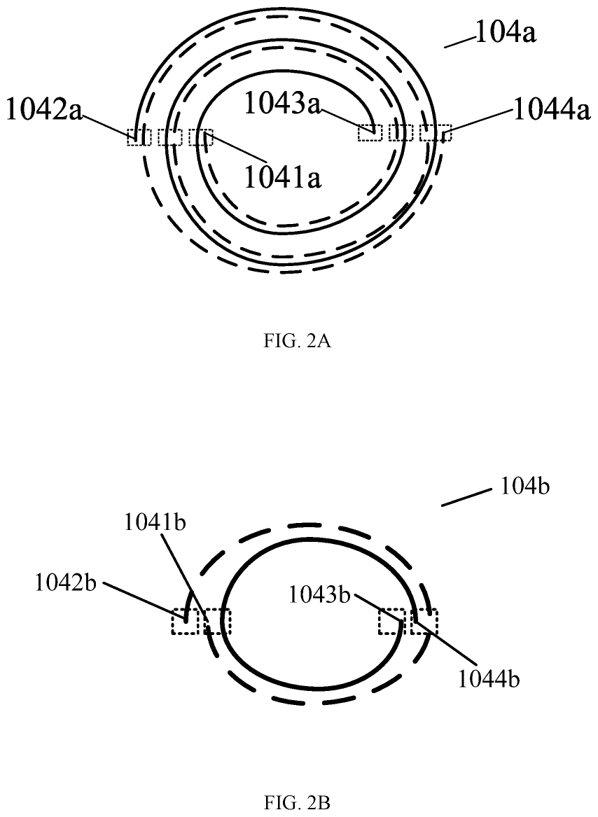

Specifically, black blocks are used to represent the coil arrangement for both the outer coil 104a and the inner coil 104b in FIG. 1. Positions of the black blocks of the outer coil 104a in FIG. 1 are in a one-to-one correspondence with positions of dotted blocks in FIG. 2A. Positions of the black blocks of the inner coil 104b in FIG. 1 are in a one-to-one correspondence with dotted blocks in FIG. 2B. The outer coil 104a shown in FIG. 2A may include two sets of coils connected in parallel. The first set of coils (represented by dashed lines in FIG. 2A) includes an input end 1041a and an output end 1044a. The second set of coils (represented by solid lines in FIG. 2A) includes an input end 1043a and an output end 1042a. In addition, the first set of coils and the second set of coils may be planar coils with a same number of turns and opposite winding directions to achieve uniform distribution of radial voltage. Similarly, the inner coil 104b shown in FIG. 2B may include two sets of coils connected in parallel. A first set of coils (represented by the dashed lines in FIG. 2B) include an input end 1041b and an output end 1042b. A second set of coils (represented by solid lines in FIG. 2B) include an input 1043b and an output 1044b. In addition, the first set of coils and the second set of coils may be both planar coils with a same number of turns and opposite winding directions to achieve uniform distribution of the radial voltage. Of course, in practical applications, the number of turns of the two sets of coils in the outer coil or the inner coil may also be different according to different needs, and a winding manner may also adopt any other method. In addition, in practical applications, the RF coil may not be divided into the inner coil and the outer coil or may also be divided into an inner coil, an intermediate coil, and an outer coil.

When the RF source 107 is turned on, through a matching action of the matcher 108, the outer coil 104a and the inner coil 104b generate an induced magnetic field, which may generate an inductively coupled plasma in the process chamber 100 through the dielectric window 103. Various reaction gases (such as Cl₂, SF₆, C₄F₈, O₂, etc.) may be introduced into the process chamber 100. Then, the induced electromagnetic field generated by the RF coil 104 may be used to cause bound electrons in a gas atom in the process chamber 100 to overcome potential to become free electrons. The free electrons that gain kinetic energy may collide with molecules, atoms, or ions to completely dissociate the gas to form a plasma. The plasma may include a large number of active particles such as electrons, ions (including positive and negative ions), excited atoms, molecules, and free radicals. The active particles may interact with a surface of a wafer that is arranged in the chamber and exposed to the plasma to cause physical-chemical reactions on the wafer material surface. Thus, the performance of the material surface may change to finish processing such as etching. In addition, in the process chamber 100, the base 101 can also be externally connected to an RF bias voltage to control ion energy bombarding the wafer.

The RF coil may include at least two parallelly-connected branches. Taking the RF coil 104 shown in FIG. 1 as an example, the first set of coils in the outer coil 104a includes a sub-branch 1 and a sub-branch 4, which are two parts of a same branch. An end of the sub-branch 1 and an end of the sub-branch 4 are connected to the input end 1041a and the output end 1044a of the first set of coils of the outer coil 104a, respectively. The other end of the sub-branch 1 and the other end of the sub-branch 4 may be connected to the output end and the input end of the matcher 108. Thus, the current may be input from the sub-branch 1 and output from sub-branch 4. Similarly, the second set of coils of the outer coil 104a may include a sub-branch 2 and a sub-branch 3, which are also two parts of a same branch. An end of the sub-branch 2 and an end of the sub-branch 3 may be connected to the output end 1042a and the input end 1043a of the second set of coils of the outer coil 104a, respectively. Thus, the current may be input from the sub-branch 3 and output from the sub-branch 2.

Similarly, the first set of coils in the inner coil 104b may include a sub-branch 5 and a sub-branch 6, which are two parts of a same branch. An end of the sub-branch 5 and the sub-branch 6 may be connected to the input end 1041b and the output end 1042b of the first set of coils of the inner coil 104b, respectively. The other end of the sub-branch 5 and the other end of the sub-branch 6 may be connected to the output end and the input end of the matcher 108. Thus, the current may be input from the sub-branch 5 and output from the sub-branch 6. Similarly, the second set of coils of the inner coil 104b may include a sub-branch 7 and a sub-branch 8, which are two parts of a same branch. An end of the sub-branch 7 and an end of the sub-branch 8 may be connected to the input end 1043b and the output end 1044b of the second set of coils. Thus, the current may be input from the sub-branch 7 and output from the sub-branch 8.

However, Since a mechanical structure of the connection bar 105 for connecting to the sets of coils in the outer coil 104a and that for connecting to the sets of coils in the inner coil 104b (such as a length of a branch of the connection bar) are different, and due to a difference in the distribution parameters caused by the limitation of the space of the ground part, the current of the at least two parallelly-connected branches of the RF coil may be caused to be different. Thus, the energy of the plasma coupled to the process chamber 100 through the dielectric window 103 may be uneven, which causes a problem that the etching process may be uneven.

In order to solve the above problems, the upper electrode mechanism of the semiconductor processing apparatus of embodiments of the present disclosure includes all functional units of the upper electrode mechanism of the semiconductor processing apparatus shown in FIG. 1. Improvement is made based on the upper electrode mechanism. The improvements are as follows.

The upper electrode mechanism in the embodiment includes a current sensor and a current adjustment device. A current sensor may be arranged on each branch of the RF coil and configured to sense the branch current of the corresponding branch. The current adjustment device may be connected to the RF coil and configured to adjust the branch current of at least one branch to cause the branch currents of the branches to be the same to achieve the uniformity of the plasma etching.

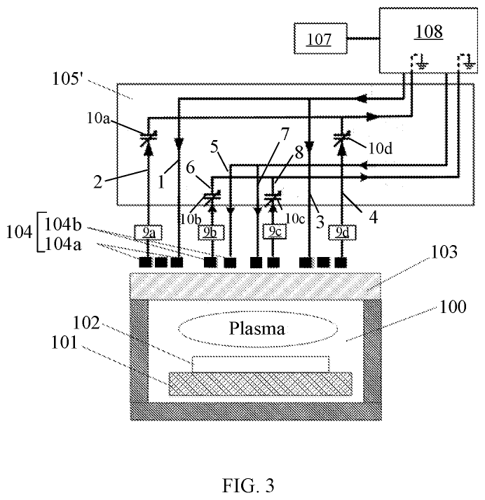

For example, with reference to FIG. 3, two current sensors (9d, 9a) may be arranged on the sub-branch 4 of the first set of coils in the outer coil 104a and the sub-branch 2 of the second set of coils in the outer coil 104a, respectively. The branch currents of the sub-branch 4 and the sub-branch 2 obtained by the two current sensors (9d, 9a), respectively, may be used as the branch currents of the two parallelly-connected branches of the outer coil 104a. Of course, in practical applications, the current sensors may also be arranged on the sub-branch 1 and the sub-branch 3, respectively. The branch currents of the sub-branch 1 and the sub-branch 3 obtained, respectively, may be used as the branch currents of the two parallelly-connected branches of the outer coil. Similarly, two current sensors (9b, 9c) may be arranged on the sub-branch 6 of the first set of coils of the inner coil 104b and the sub-branch 8 of the second set of coils in the inner coil 104b, respectively. The branch currents of the sub-branch 6 and the sub-branch 7 obtained by the two current sensors (9b, 9c) may be used as the branch currents of the two parallelly-connected branches of the inner coil 104b. Of course, in practical applications, current sensors may also be arranged on the sub-branch 5 and the sub-branch 7, respectively. The branch currents of the sub-branch 5 and the sub-branch 7 obtained respectively may be used as the branch currents of the two parallelly-connected branches of the inner coil. By detecting the branch current of each coil of the RF coil by the current sensor, whether the branch currents of the two parallelly-connected branches of the RF coil are different may be determined. By using the current adjustment device to adjust the branch current, the branch currents of the two parallelly-connected branches of each coil in the RF coil may be made same. Thus, the uniformity of the plasma etching may be achieved.

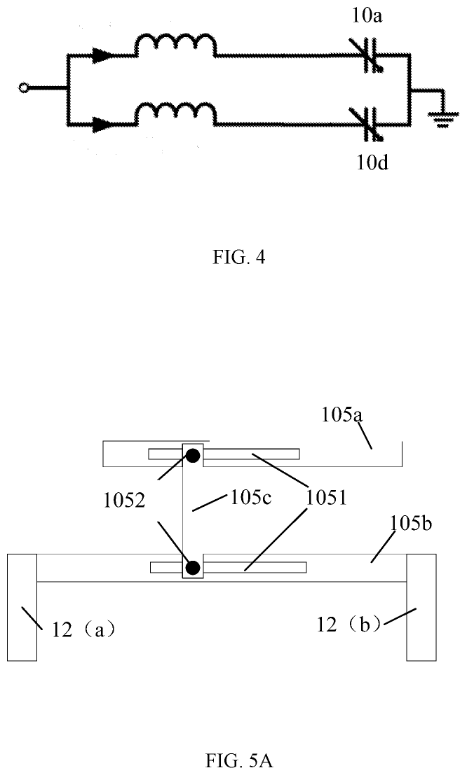

The above current adjustment device may have a plurality of structures. For example, as shown in FIG. 3, the current adjustment device includes a capacitance adjustment assembly. The capacitance adjustment assembly may be connected to the at least two parallelly-connected branches and configured to adjust capacitance of at least one branch to cause the branch currents of the branches to be the same. Specifically, the above capacitance adjustment assembly may include at least two adjustable capacitors. The at least two adjustable capacitors may be arranged on at least two parallelly-connected branches in a one-to-one correspondence. Optionally, as shown in FIG. 3, the capacitance adjustment assembly includes adjustable capacitors (such as adjustable capacitor 10a, adjustable capacitor 10b, adjustable capacitor 10c, and adjustable capacitor 10d) arranged on two parallelly-connected branches of each coil. Thus, an equivalent circuit diagram including the branch where the adjustable capacitor 10a is located and the parallelly-connected branch where the adjustable capacitor 10d is located is shown in FIG. 4. In addition, an initial capacitance value of the adjustable capacitor of each branch may be the same. For example, the initial value of the adjustable capacitor may be set to 100 pF, which can reduce the change in impedance as a whole. Thus, the impact on the etching rate may be reduced. An adjustable range of each adjustable capacitor may be predetermined. For example, the predetermined adjustable range may be the initial value±10 pF. That is, the adjustable capacitor may be precisely adjusted within the adjustable range.

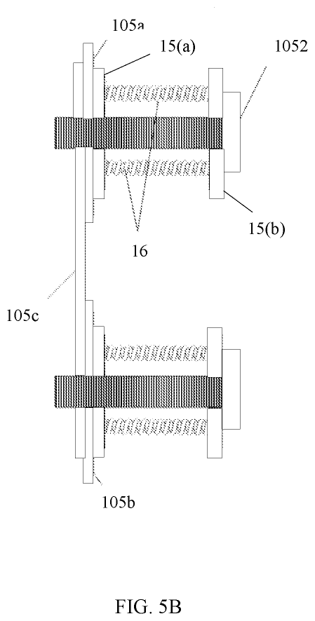

For another example, as shown in FIG. 5A and FIG. 5B, the current adjustment device further includes a first connection bar 105a, a second connection bar 105b, and a mobile connection bar 105c, which constitute the connection bar 105′ in the upper electrode mechanism. Compared with the connection bar 105 in FIG. 1, the connection bar 105′ adopted in the embodiment can be configured to have a function of transitional connection between the RF coil 104 and the matcher 108. Based on this, the connection bar 105′ used in the embodiment may also have a function of branch current adjustment. Specifically, the first connection bar 105a may be connected to the RF source 107 through the matcher 108. The second connection bar 105b may be respectively connected to at least two parallelly-connected branches (12(a) and 12(b)). The mobile connection bar 105c may be movably connected to the first connection bar 105a and the second connection bar 105b. A connection point between the mobile connection bar 105c and the first connection bar 105a may move along the first connection bar 105a. A connection point between the mobile connection bar 105c and the second connection bar 105b may move along the second connection bar 105b.

In some embodiments, as shown in FIG. 5A, the first connection bar 105a and the second connection bar 105b are parallel to each other. The mobile connection bar 105c is perpendicular to the first connection bar 105a and the second connection bar 105b. Two ends of the mobile connection bar 105c may be movably connected to the first connection bar 105a and the second connection bar 105b, respectively. Thus, the movement of the mobile connection bar 105c may be facilitated, and processing difficulty may be reduced.

As shown in FIG. 5A and FIG. 5B, the current adjustment device further includes two connection assemblies, which are configured to movably connect the two ends of the mobile connection bar 105c to the first connection bar 105a and the second connection bar 105b, respectively. Each connection assembly includes a first washer 15(a), a second washer 15(b), an elastic member 16, and a screw 1052. A strip-shaped groove 1051 is formed on each of the first connection bar 105a and the second connection bar 105b. The two ends of the mobile connection bar 105c may include threaded holes matching the screws 1052, respectively. The first washer 15(a) and the second washer 15(b) may include through-holes for the screw 1052 to pass through. The first washer 15(a) and the second washer 15(b) are arranged opposite to each other. The first washers 15(a) may be movably connected to the first connection bar 105a and the second connection bar 105b. The second connection bar 105b may be arranged attached to a corresponding one of the connection assemblies. The elastic member 16 is arranged between the first washer 15(a) and the second washer 15(b). The screw 1052 passes from a side of the second washer 15(b) away from the first washer 15(a) through, in sequence, the through-hole of the second washer 15(b), the elastic member 16, the through-hole of the first washer 15(a), and the strip-shaped groove of one of the first connection bar 105a and the second connection bar 105b corresponding to the connection assembly, and is threadedly connected to the threaded hole of the mobile connection bar 105c.

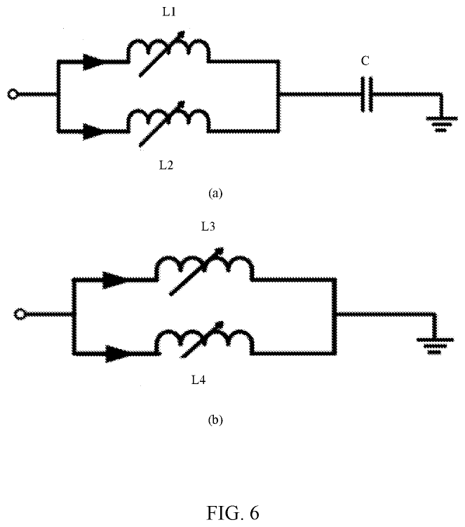

When the mobile connection bar 105c needs to slide, the screws 1052 may be loosened to reduce the pressure of the elastic members 16 to reduce frictional forces between the mobile connection bar 105c and the first connection bar 105a and between the mobile connection bar 105c and the second connection bar 105b. Thus, the mobile connection bar 105c may slide left and right along the strip-shaped grooves 1051 on the first connection bar 105a and the second connection bar 105b. The screws 1052 may be tightened until the elastic members 16 are fully compressed to fix the mobile connection bar 105c at a certain position without further sliding. The equivalent circuit diagram including the mobile connection bar 105c, the second connection bar 105b, and the branch where the second connection bar 105b is located is shown in FIG. 6. FIG. 6(a) is an equivalent circuit diagram including a set of branches of the inner coil 104b (i.e., the first connection bar 105a and the second connection bar 105b correspond to a set of branches of the inner coil 104b, respectively). FIG. 6(b) is an equivalent circuit diagram including a set of branches of the outer coil 104a (i.e., the first connection bar 105a and the second connection bar 105b correspond to a set of branches of the outer coil 104a, respectively). L1 and L2 are a set of coils corresponding to the inner coils in the RF coil. L3 and L4 are a set of coils corresponding to the outer coils in the RF coil. The inductance of the branch may be a variable inductance.

In summary, in the upper electrode mechanism of the semiconductor processing apparatus of embodiments of the present disclosure, by detecting the branch current of the corresponding branch of the at least two parallelly-connected branches of the RF coil through the current sensor, the branch current of the at least one branch may be adjusted by the current adjustment device according to the detected branch current to cause the branch currents of the branches to be the same. Thus, the situation that the energy of the plasma coupled to the chamber through the dielectric window is uneven due to the different currents of the parallelly-connected branches of the coil may be avoided. Thus, the uniformity of the etching process may be ensured.

### Embodiment 2

A semiconductor processing apparatus of embodiments of the present disclosure includes a process chamber. The process chamber includes the upper electrode mechanism described in Embodiment 1.

In the semiconductor processing apparatus of embodiments of the present disclosure, by providing the upper electrode mechanism as described in Embodiment 1, the situation that the energy of the plasma coupled to the chamber through the dielectric window is uneven due to the different currents of the parallelly-connected branches of the coil may be avoided. Thus, the uniformity of the etching process may be ensured.

### Embodiment 3

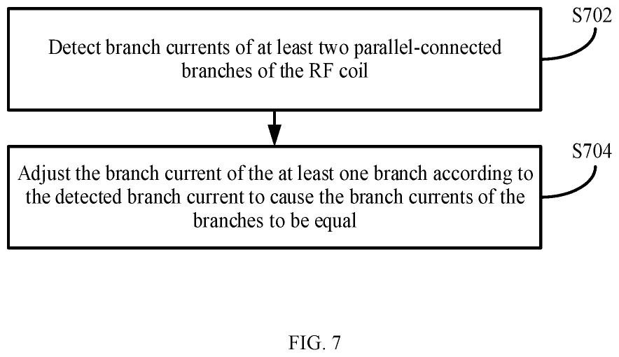

As shown in FIG. 7, embodiments of the present disclosure provide a current control method for the RF coil in the semiconductor processing apparatus. The execution body of the method may be a controller of the semiconductor processing apparatus in Embodiment 2, the semiconductor processing apparatus including the current adjustment mechanism, a server of the semiconductor processing apparatus, or a server cluster including a plurality of servers. The method specifically includes the following steps.

At S702, branch currents of at least two parallelly-connected branches of the RF coil are detected.

The RF coil may include at least two coils configured to generate a plasma. The semiconductor processing apparatus may be an apparatus configured to perform an etching process on a wafer surface.

The above RF coil may include at least two parallelly-connected branches. By taking the RF coil 104 shown in FIG. 1 as an example, the first set of coils in the outer coil 104a includes sub-branch 1 and sub-branch 4, which are two parts of the same branch. An end of sub-branch 1 and an end of sub-branch 4 are connected to the input end 1041a and the output end 1044a of the first set of coils of the outer coil 104a. The other end of the sub-branch 1 and the other end of sub-branch 4 are connected to the output end and the input end of the matcher 108, respectively. Thus, the current may be input from sub-branch 1 and output by sub-branch 4. Similarly, the second set of coils of the outer coil 104a includes sub-branch 2 and sub-branch 3, which are also two parts of the same branch. An end of sub-branch 2 and an end of sub-branch 3 are connected to the output end 1042a and the input end 1043a of the second set of coils of the outer coil 104a. Thus, the current may be input from sub-branch 3 and output by sub-branch 2.

Similarly, the first set of coils in the inner coil 104b includes sub-branch 5 and sub-branch 6, which are two parts of the same branch. An end of sub-branch 5 and an end of sub-branch 6 are connected to the input end 1041b and output end 1042b of the first set of coils of the inner coil 104b, respectively. The other end of sub-branch 5 and the other end of sub-branch 6 may be connected to the output end and the input end of the macher 108. Thus, the current may be input from sub-branch 5 and output by sub-branch 6. Similarly, the second set of coils in the inner coil 104b include sub-branch 7 and sub-branch 8, which are also two parts of the same branch. An end of sub-branch 7 and an end of sub-branch 8 may be connected to the input end 1043b and the output end 1044b of the second set of coils of the coil 104b, respectively. Thus, the current may be input from sub-branch 7 and output by sub-branch 8.

The above description is made by taking the RF coil including the inner coil and the outer coil as an example. In practical application scenarios, the semiconductor processing apparatus may further include a plurality of coils configured to generate the plasma, which may be different when the practical application scenarios are different and are not limited in embodiments of the present disclosure.

For example, with reference to FIG. 3, the two current sensors (9d, 9a) are arranged at sub-branch 4 of the first set of coils in the outer coil 104a and sub-branch 2 of the second set of coils in the outer coil 104a, respectively. The branch currents of sub-branch 4 and sub-branch 2 obtained by the two current sensors (9d, 9a) respectively may be used as the branch currents of the two parallelly-connected branches of the outer coil 104a. Of course, in practical applications, the current sensors may also be arranged at sub-branch 1 and sub-branch 3 and be configured to obtain the branch currents of sub-branch 1 and sub-branch 3 as the branch currents of the two parallelly-connected branches of the outer coil. Similarly, the two current sensors (9b, 9c) may be arranged at sub-branch 6 of the first set of coils in the inner coil 104b and sub-branch 8 of the second set of coils in the inner coil 104b. The two branch currents of sub-branch 6 and sub-branch 7 obtained by the current sensors (9b, 9c) respectively are used as the branch currents of the two parallelly-connected branches of the inner coil 104b. Of course, in practical applications, the current sensors may also be arranged at sub-branch 5 and sub-branch 7. The branch currents of sub-branch 5 and sub-branch 7 obtained respectively may be used as the branch currents of the two parallelly-connected branches of the inner coil. The branch current of each coil of the RF coil may be detected by the current sensor to know whether the situation that the coil having two parallelly-connected branches with different branch currents exists. Then, the branch current may be adjusted by the current adjustment device to cause the branch currents of the two parallelly-connected branches of each coil in the RF coil to be made the same. Thus, the uniformity of the plasma etching may be realized.

At S704, the branch current of the at least one branch is adjusted according to the detected branch current to cause the branch currents of the branches to be equal.

For example, as shown in FIG. 3, the current adjustment device includes a capacitance adjustment assembly. The capacitance adjustment assembly is connected to the at least two parallelly-connected branches to adjust the capacitance of the at least one branch to cause the branch currents of the branches to be equal. Specifically, the above capacitance adjustment assembly includes at least two adjustable capacitors. The at least two adjustable capacitors are arranged on at least two parallelly-connected branches in a one-to-one correspondence. In some embodiments, as shown in FIG. 3, the capacitance adjustment assembly includes adjustable capacitors (e.g., adjustable capacitor 10a, adjustable capacitor 10b, adjustable capacitor 10c, and adjustable capacitor 10d) arranged at two parallelly-connected branches at each coil. Thus, the equivalent circuit diagram including the branch where the adjustable capacitor 10a is located and the parallelly-connected branch where the adjustable capacitor 10d is located is shown in FIG. 4. In addition, an initial capacitance value of the adjustable capacitor of each branch may be the same. For example, the initial value of the adjustable capacitor may be set to 100 pF, which can reduce the change in impedance as a whole. Thus, the impact on the etching rate may be reduced. An adjustable range of each adjustable capacitor may be predetermined. For example, the predetermined adjustable range may be the initial value±10 pF. That is, the adjustable capacitor may be precisely adjusted within the adjustable range.

Based on the above current adjustment device, the above step S704 includes:

according to the detected branch current, adjusting the capacitance value of the adjustable capacitor on at least one branch to cause the branch currents of the branches to be equal.

In practical applications, if the branch currents of sub-branch 2 and sub-branch 4 of the outer coil are detected to be not equal, the capacitance of the current of the outer coil may be adjusted according to the branch currents of sub-branch 2 and sub-branch 4. Similarly, if the branch currents of the two parallelly-connected branches of the inner coil are not equal, the capacitance of the current of the inner coil may also be adjusted according to the branch currents of the two parallelly-connected branches of the inner coil. Thus, the branch currents of the parallelly-connected branches on each coil may be made equal to improve the uniform distribution of the plasma to improve the etching uniformity of the semiconductor processing apparatus.

As shown in FIG. 5A and FIG. 5B, the current adjustment device further includes the first connection bar 105a, the second connection bar 105b, and the mobile connection bar 105c. The first connection bar 105a is connected to the RF source 107 through the matcher 108. The second connection bar 105b is connected to the at least two parallelly-connected branches (12(a) and 12(b)). The mobile connection bar 105c may be movably connected to the first connection bar 105a and the second connection bar 105b. The connection point between the mobile connection bar 105c and the first connection bar 105a may move along the first connection bar 105a. The connecting point between the mobile connection bar 105c and the second connection bar 105b may move along the second connection bar 105b.

Based on the above current adjustment device, step S704 includes:

adjusting lengths of connection parts of the first connection bar 105a and the second connection bar 105b between the branches and the matcher 108 to cause the branch currents of the branches to be equal.

In some embodiments, as shown in FIG. 5A and FIG. 5B, the current adjustment device further includes the two connection assemblies, which are configured to movably connect the two ends of the mobile connection bar 105c to the first connection bar 105a and the second connection bar 105b, respectively. Each connection assembly includes a first washer 15(a), a second washer 15(b), an elastic member 16, and a screw 1052. A strip-shaped groove 1051 is arranged on each of the first connection bar 105a and the second connection bar 105b. The two ends of the mobile connection bar 105c may include threaded holes matching the screws 1052, respectively. The first washer 15(a) and the second washer 15(b) may include through-holes for the screws 1052 to pass through. The first washer 15(a) and the second washer 15(b) are arranged opposite to each other. The first washer 15(a) may be movably connected to the first connection bar 105a and the second connection bar 105b. The second connection bar 105b may be arranged attached to a corresponding one of the connection assemblies. The elastic member 16 is arranged between the first washer 15(a) and the second washer 15(b). The screw 1052 passes from a side of the second washer 15(b) away from the first washer 15(a) through, in sequence, the through-hole of the second washer 15(b), the elastic member 16, the through-hole of the first washer 15(a), and the strip-shaped groove of one of the first connection bar 105a and the second connection bar 105b corresponding to the connection assembly, and is threadedly connected to the threaded hole of the mobile connection bar 105c.

Based on the above current adjustment device, adjusting the lengths of the connection parts of the first connection bar 105a and the second connection bar 105b between the branches and the matcher 108 further includes:

loosening the screw 1052 to reduce the compression of the elastic member 16;

moving the two ends of the mobile connection bar 105c along the strip-shaped groove 1051 to adjust the positions of the connection points where the two ends of the movable connection bar 105c are connected to the first connection bar 105a and the second connection bar 105b, respectively; and tightening the screw 1052 to increase the compression amount of the elastic member 16 to fix the mobile connection bar 105c at the adjusted positions.

Specifically, when the mobile connection bar 105c needs to slide, the screw 1052 may be loosened to reduce the pressure of the elastic member 16 to reduce a frictional force between the mobile connection bar 105c and the first connection bar 105a and between the mobile connection bar 105c and the second connection bar 105b. Thus, the mobile connection bar 105c may slide left and right along the strip-shaped grooves 1051 on the first connection bar 105a and the second connection bar 105b. The screw 1052 may be tightened until the elastic member 16 are fully compressed to fix the mobile connection bar 105c at a certain position without further sliding. The equivalent circuit diagram including the mobile connection bar 105c, the second connection bar 105b, and the branch where the second connection bar 105b is located is shown in FIG. 6. FIG. 6(a) is an equivalent circuit diagram including a set of branches of the inner coil 104b (i.e., the first connection bar 105a and the second connection bar 105b correspond to a set of branches of the inner coil 104b, respectively). FIG. 6(b) is an equivalent circuit diagram including a set of branches of the outer coil 104a (i.e., the first connection bar 105a and the second connection bar 105b correspond to a set of branches of the outer coil 104a, respectively). L1 and L2 are a set of coils corresponding to the inner coils in the RF coil. L3 and L4 are a set of coils corresponding to the outer coils in the RF coil. The inductance of the branch may be a variable inductance.

In the current control method of the semiconductor processing apparatus of embodiments of the present disclosure, by detecting the branch currents of the corresponding branch of the at least two parallelly-connected branches of the RF coil through the current sensor, the branch current of the at least one branch may be adjusted by the current adjustment device according to the detected branch currents to cause the branch currents of the branches to be equal. Thus, the situation that the energy of the plasma coupled to the chamber through the dielectric window is uneven due to the different currents of the parallelly-connected branches of the coil may be avoided. Thus, the uniformity of the etching process may be ensured.

### Embodiment 4

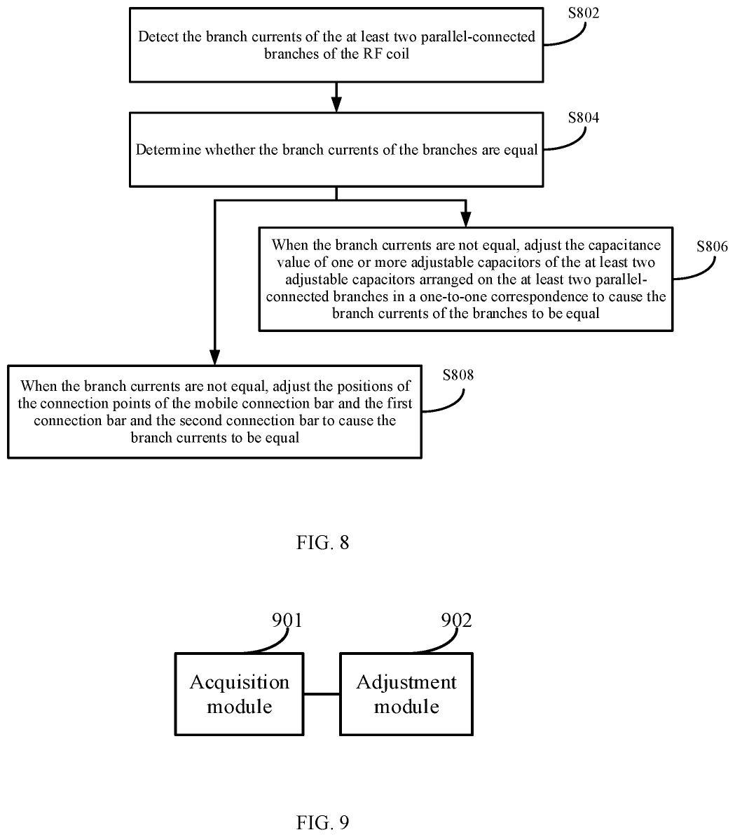

As shown in FIG. 8, embodiments of the present disclosure provide a current control method of a semiconductor processing apparatus. The method specifically includes the following steps.

At S802, the branch currents of the at least two parallelly-connected branches of the RF coil are detected.

The two parallelly-connected branches may be two parallelly-connected input branches of the RF coil or two parallelly-connected output branches of the RF coil.

At S804, whether the branch currents of the branches are equal is determined.

When the branch currents are not equal, the branch currents of the branches may be adjusted according to the following step S806 or step S808.

At S806, when the branch currents are not equal, the capacitance value of one or more adjustable capacitors of the at least two adjustable capacitors arranged on the at least two parallelly-connected branches in a one-to-one correspondence is adjusted to cause the branch currents of the branches to be equal.

Preferably, the capacitance of the adjustable capacitors on the branches can be adjusted by manual adjustment to cause the branch currents of the branches to be equal. Alternatively, the corresponding capacitance value may be determined by the controller based on a predetermined corresponding relationship of the current and the capacitor. The predetermined corresponding relationship of the current and capacitor is shown in Table 1.

TABLE 1

| | Capacitance value |
|---|---|
| Current | of capacitor |
| Not greater than I₁ | C1 |
| Not less than I₁ and not greater than I₂ | C2 |
| Greater than I₂ | C3 |

If a coil with different branch currents of the two parallelly-connected branches (e.g., branch 1 and branch 2) exists in the RF coil, the branch current of the branch 1 of the coil may be not less than I₁ and not greater than I₂, and the branch current of the branch 2 of the coil is not greater than I₂, the capacitance used to adjust the branch 1 is determined to be C2, and the capacitance used to adjust the branch 2 is determined to be C3 based on the predetermined corresponding relationship in Table 1.

The above determination method of the predetermined corresponding relationship may be an optional and achievable determination method. In actual application scenarios, a plurality of different determination methods may be included and may be different according to different practical application scenarios, which are not limited in embodiments of the present disclosure.

At S808, when the branch currents are not equal, the positions of the connection points of the mobile connection bar at the first connection bar and the second connection bar are adjusted to cause the branch currents to be equal.

In the current control method of the semiconductor processing apparatus of embodiments of the present disclosure, the branch current of the corresponding branch in the at least two parallelly-connected branches of the RF coil may be detected by the current sensor. The branch current of the at least one branch may be adjusted by the current adjustment device according to the detected branch currents to cause the branch currents of the branches to be equal. Thus, the situation that the energy of the plasma coupled to the chamber through the dielectric window is uneven due to the different currents of the parallelly-connected branches of the coil may be avoided. Thus, the uniformity of the etching process may be ensured.

### Embodiment 5

The above is the current control method of the semiconductor processing apparatus of embodiments of the present disclosure. Based on the same concept, embodiments of the present disclosure also provide a current adjustment device of the semiconductor processing apparatus as shown in FIG. 9.

The current adjustment device of the semiconductor processing apparatus includes an acquisition module 901 and an adjustment module 902.

The acquisition module 901 is configured to detect the branch currents of the at least two parallelly-connected branches of the RF coil.

The adjustment module 902 is configured to adjust the branch current of the at least one branch according to the detected branch currents to cause the branch currents of the branches to be equal.

In embodiments of the present disclosure, the above adjustment module 902 is configured to:

according to the detected branch currents, adjust the capacitance value of the adjustable capacitor on the at least one branch to cause the branch currents of the branches to be equal.

In embodiments of the present disclosure, the above adjustment module 902 is configured to:

by moving the mobile connection bar, adjust the lengths of the connection parts of the first connection bar and the second connection bar between the branches and the matcher to cause the branch currents of the branches to be equal.

In embodiments of the present disclosure, the above adjustment module 902 is configured to:

loosen the screw to reduce the compression of the elastic member;

move the two ends of the mobile connection bar along the strip-shaped groove to adjust the positions of the connection points where the two ends of the mobile connection bar are respectively connected to the first connection bar and the second connection bar; and

tighten the screw to increase the compression of the elastic member to fix the mobile connection bar at the adjusted position.

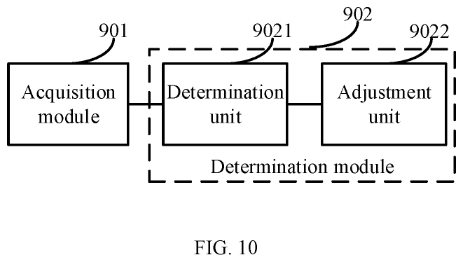

In some embodiments, as shown in FIG. 10, the above adjustment module 902 further includes:

a determination unit 9021 configured to determine whether the currents of all branches are equal; and

an adjustment unit 9022 configured to adjust the branch current of the at least one branch according to the detected branch current when the branch currents are not equal to cause the branch currents of each branch are equal.

Embodiments of the present disclosure provide the current adjustment device for the semiconductor processing apparatus. The branch current of the corresponding branch in the at least two parallelly-connected branches of the RF coil may be detected by the current sensor. The branch current of the at least one branch may be adjusted by the current adjustment device according to the detected branch currents to cause the branch currents of the branches to be equal. Thus, the situation that the energy of the plasma coupled to the chamber through the dielectric window is uneven due to the different currents of the parallelly-connected branches of the coil may be avoided. Thus, the uniformity of the etching process may be ensured.

Those skilled in the art should understand that embodiments of the present disclosure may be provided as a method, system, or computer program product. Thus, the present disclosure may adopt forms of entirely hardware embodiments, entirely software embodiments, or embodiments combining software and hardware. Furthermore, the present disclosure may adopt a form that a computer program product is implemented in one or more computer-readable storage medium (including, but not limited to, disk storage, CD-ROM, optical storage, etc.) including computer-readable program codes.

The present disclosure is described with reference to the methods, apparatuses (systems), and flowchart and/or the block diagram of the computer program product. It should be understood that the computer program instructions may be used to implement each flow and/or block in the flowcharts and/or block diagrams and a combination of flows and/or blocks in the flowcharts and/or block diagrams. The computer program instructions may be provided to a processor of a general purpose computer, special purpose computer, embedded processor, or another programmable data processing apparatus to produce a machine to cause the instructions executed by the processor of the computer or the other programmable data processing apparatus to generate a device to implement one or more flows of the flowchart and/or a determined function of one block or more blocks of the block diagram.

These computer program instructions may also be stored in a computer-readable memory capable of directing the computer or other programmable data processing apparatus to function in a particular manner. Thus, the instructions stored in the computer-readable memory may be used to generate a product including the instruction device. The instruction device may be used to implement the function determined in one or more flows in the flowchart and/or one or more blocks in the block diagram.

These computer program instructions can also be loaded on a computer or another programmable data processing apparatus to cause a series of operational steps to be performed on the computer or the other programmable apparatus to generate processes implemented by the computer. Thus, the instructions executed by the computer or the other programmable data processing apparatus may be used to provide steps for implementing the function determined in one or more flows in the flowchart and/or one or more blocks in the block diagram.

Memory may include non-persistent memory of the computer-readable medium, random access memory (RAM), and/or non-volatile memory, such as read-only memory (ROM) or flash memory (flash RAM). Memory may be an example of a computer-readable medium.

It should also be noted that the terms “comprising,” “including,” or any other variation thereof are intended to encompass a non-exclusive inclusion such that a process, method, article, or apparatus comprising a series of elements includes not only those elements, but also other elements not expressly listed, or elements that are inherent to such the process, method, article, or apparatus. Without further limitation, an element defined by a phrase “comprising a . . . ” does not preclude the presence of additional identical elements in the process, method, article, or apparatus that includes the element.

Those skilled in the art should understand that embodiments of the present disclosure may be provided as a method, system, or computer program product. Accordingly, the present disclosure may adopt a form of an entire hardware embodiment, an entire software embodiment, or an embodiment combining software and hardware aspects. Furthermore, the present disclosure may adopt a form that a computer program product is implemented in one or more computer-readable storage media (including, but not limited to, disk storage, CD-ROM, optical storage, etc.) including computer-readable program codes.

The above descriptions are merely embodiments of the present disclosure and are not intended to limit the present disclosure. For those skilled in the art, various modifications and variations may be made to the present disclosure. Any modification, equivalent replacement, and improvement made within the spirit and principle of the present disclosure shall be included within the scope of the claims of the present application.

1.-12. (canceled)

13. An upper electrode mechanism of a semiconductor process apparatus comprising:
a radio frequency (RF) coil including two parallelly-connected branches;
two current sensors each arranged on one of the branches and configured to detect a branch current of a corresponding one of the two branches; and
a current adjustment device connected to the RF coil and configured to adjust the branch current of at least one branch of the two branches according to the detected branch currents to cause the branch currents of the two branches to be equal.

14. The upper electrode mechanism according to claim 13, wherein the current adjustment device includes a capacitance adjustment assembly connected to the two branches and configured to adjust a capacitance of the at least one branch.

15. The upper electrode mechanism according to claim 14, wherein the capacitance adjustment assembly includes two adjustable capacitors arranged on the two branches in a one-to-one correspondence.

16. The upper electrode mechanism according to claim 13, wherein the current adjustment device includes:
a first connection bar connected to an RF source through a matcher;
a second connection bar connected to the two branches; and
a mobile connection bar movably connected to the first connection bar and the second connection bar, a connection point between the mobile connection bar and the first connection bar being movable along the first connection bar, and a connection point between the mobile connection bar and the second connection bar being movable along the second connection bar.

17. The upper electrode mechanism according to claim 16, wherein:
the first connection bar and the second connection bar are parallel to each other; and
the mobile connection bar is perpendicular to the first connection bar and the second connection bar.

18. The upper electrode mechanism according to claim 16, wherein two ends of the mobile connection bar are movably connected to the first connection bar and the second connection bar, respectively.

19. The upper electrode mechanism according to claim 18, wherein the current adjustment device further includes:
two connection assemblies configured to movably connect the two ends of the mobile connection bar to the first connection bar and the second connection bar, each of the two connection assemblies including:
a first washer movably connected to one of the first connection bar and the second connection bar;
a second washer arranged opposite to the first washer;
an elastic element arranged between the first washer and the second washer; and
a screw passing from a side of the second washer away from the first washer through, in sequence, a through-hole of the second washer, the elastic element, a through-hole of the first washer, a stripe-shaped groove of the one of the first connection bar and the second connection bar, and threadedly connected to a threaded hole at one of the two ends of the mobile connection bar.

20. The upper electrode mechanism according to claim 13, wherein:
the RF coil includes an inner coil and an outer coil;
the two parallelly-connected branches are first two parallelly-connected branches of the inner coil; and
the outer coil includes second two parallelly-connected branches.

21. A semiconductor processing apparatus comprising:
a process chamber; and
an upper electrode mechanism provided at the process chamber and including:
a radio frequency (RF) coil including two parallelly-connected branches;
two current sensors each arranged on one of the branches and configured to detect a branch current of a corresponding one of the two branches; and
a current adjustment device connected to the RF coil and configured to adjust the branch current of at least one branch of the two branches according to the detected branch currents to cause the branch currents of the two branches to be equal.

22. The semiconductor processing apparatus according to claim 21, wherein the current adjustment device includes a capacitance adjustment assembly connected to the two branches and configured to adjust a capacitance of the at least one branch.

23. The semiconductor processing apparatus according to claim 22, wherein the capacitance adjustment assembly includes two adjustable capacitors arranged on the two branches in a one-to-one correspondence.

24. The semiconductor processing apparatus according to claim 21, wherein the current adjustment device includes:
a first connection bar connected to an RF source through a matcher;
a second connection bar connected to the two branches; and
a mobile connection bar movably connected to the first connection bar and the second connection bar, a connection point between the mobile connection bar and the first connection bar being movable along the first connection bar, and a connection point between the mobile connection bar and the second connection bar being movable along the second connection bar.

25. The semiconductor processing apparatus according to claim 24, wherein:
the first connection bar and the second connection bar are parallel to each other; and
the mobile connection bar is perpendicular to the first connection bar and the second connection bar.

26. The semiconductor processing apparatus according to claim 24, wherein two ends of the mobile connection bar are movably connected to the first connection bar and the second connection bar, respectively.

27. The semiconductor processing apparatus according to claim 26, wherein the current adjustment device further includes:
two connection assemblies configured to movably connect the two ends of the mobile connection bar to the first connection bar and the second connection bar, each of the two connection assemblies including:
a first washer movably connected to one of the first connection bar and the second connection bar;
a second washer arranged opposite to the first washer;
an elastic element arranged between the first washer and the second washer; and
a screw passing from a side of the second washer away from the first washer through, in sequence, a through-hole of the second washer, the elastic element, a through-hole of the first washer, a stripe-shaped groove of the one of the first connection bar and the second connection bar, and threadedly connected to a threaded hole at one of the two ends of the mobile connection bar.

28. The semiconductor processing apparatus according to claim 21, wherein:
the RF coil includes an inner coil and an outer coil;
the two parallelly-connected branches are first two parallelly-connected branches of the inner coil; and
the outer coil includes second two parallelly-connected branches.

29. A current control method for a radio frequency (RF) coil of an upper electrode mechanism of a semiconductor process apparatus comprising:
detecting branch currents of two parallelly-connected branches of the RF coil; and
adjusting, according to the detected branch currents, the branch current of at least one branch of the two branches to cause the branch currents of the two branches to be equal.

30. The method according to claim 29, wherein:
the upper electrode mechanism further includes two adjustable capacitors arranged on the two branches in a one-to-one correspondence; and
adjusting the branch current of the at least one branch includes adjusting, according to the detected branch currents, a capacitance value of the adjustable capacitor on each of the at least one branch to cause the branch currents of the two branches to be equal.

31. The method according to claim 29, wherein:
the upper electrode mechanism further includes:
a first connection bar connected to an RF source through a matcher;
a second connection bar connected to the two branches; and
a mobile connection bar movably connected to the first connection bar and the second connection bar, a connection point between the mobile connection bar and the first connection bar being movable along the first connection bar, and a connection point between the mobile connection bar and the second connection bar being movable along the second connection bar; and
adjusting the branch current of the at least one branch includes moving the mobile connection bar to adjust lengths of connection parts of the first connection bar and the second connection bar between the at least one branch and the matcher, to cause the branch currents of the two branches to be equal.

32. The method according to claim 31, wherein:
the upper electrode mechanism further includes two connection assemblies configured to movably connect two ends of the mobile connection bar to the first connection bar and the second connection bar, each of the two connection assemblies including:
a first washer movably connected to one of the first connection bar and the second connection bar;
a second washer arranged opposite to the first washer;
an elastic element arranged between the first washer and the second washer; and
a screw passing from a side of the second washer away from the first washer through, in sequence, a through-hole of the second washer, the elastic element, a through-hole of the first washer, a stripe-shaped groove of the one of the first connection bar and the second connection bar, and threadedly connected to a threaded hole at one of the two ends of the mobile connection bar; and
adjusting the lengths of the connection parts includes:
loosening the screws to reduce compression amounts of the elastic elements;
moving the two ends of the mobile connection bar along the stripe-shaped grooves of the first connection bar and the second connection bar to adjust positions of connection points where the two ends of the mobile connection bar are connected to the first connection bar and the second connection bar, respectively; and
tightening the screws to increase the compression amounts of the elastic elements to fix the mobile connection bar at the adjusted positions.
